(19) United States
(12) Patent Application Publication
(10) Pub. No.: US 2007/0222471 A1
(43) Pub. Date: Sep. 27, 2007

(54) Front and back side dynamically-biased photon emission microscopy

(76) Inventor: Yee Chieng Tan, Singapore (SG)

Correspondence Address: HARNESS, DICKEY, & PIERCE, P.L.C, 7700 BONHOMME, STE 400, ST. LOUIS, MO, 63105, US

(21) Appl. No.: 11/387,334

(22) Filed: Mar. 23, 2006

(51) Int. Cl. G01R 31/26

(52) U.S. Cl. 324/765

(57) ABSTRACT

An apparatus for testing emissions from a packaged integrated circuit is described. The apparatus comprises an ATE for generating input stimulus to said integrated circuit, a universal PEM board. The apparatus further has an electrical connector between said ATE and said universal PEM board and means for wiring the connections from ATE leads to pin leads of said packaged integrated circuit so that the packaged integrated circuit can be biased and stimulated correctly. Jumper wires are provided to allow many to one and one to many connections; and the apparatus includes a photodetector to collect the emitted photons.

### TECHNICAL FIELD

This invention relates to a system for performing front and back side dynamically-biased photon emission microscopy.

### BACKGROUND ART

Emission microscopy is used to locate failure modes by observing the photon emissions from failure sites in integrated circuit semiconductor wafers that are stimulated with electrical test signals. Until recently, front side emission microscopy, i.e., observation of the front side of the wafer or packaged part, is a well-used and successful methodology which is fairly easy to integrate into a probing environment. As such many probe stations have been produced that ultimately have been fitted with emission microscopes for this purpose.

The problem with front side emission testing is that often the tell tale light emissions are masked by sub surface metal, dopants and other obscurities. To get at the information required in these types of emission microscopy approaches, a view of the backside of the wafer for emitted photons is advantageous.

### DISCLOSURE OF INVENTION

An object of at least one embodiment of the invention is to provide an improved apparatus for testing front and back emissions from a packaged integrated circuit or at least to provide the industry or the public with a useful choice.

Accordingly what is needed is an apparatus for testing emissions from an packaged integrated circuit having:

an ATE for generating input stimulus to said integrated circuit;

a universal PEM board;

an electrical connector between said ATE and said universal PEM board;

means for wiring the connections from ATE leads to pin leads of said packaged integrated circuit so that the packaged integrated circuit can be biased and stimulated correctly;

jumper wires providing the ability to allow many to one an one to many connections; and

a photodetector to collect the emitted photons.

Preferably said means for wiring the connections from ATE leads to pin leads of said packaged integrated circuit is a UPB and wherein said UPB has an opening corresponding to the packaging to allow said photodetector access to the back of said packaged integrated circuit

Preferably said means for wiring the connections from ATE leads to pin leads of said packaged integrated circuit is a UPB and wherein said UPB has an opening corresponding to the packaging to allow said photodetector access to the front of said packaged integrated circuit

Preferably said apparatus allows both front and back detection of photo emissions.

Preferably said jumper wires are pogo connectors.

### BRIEF DESCRIPTION OF THE DRAWINGS

FIG. 1 is a flow diagram illustrating the process of the present invention;

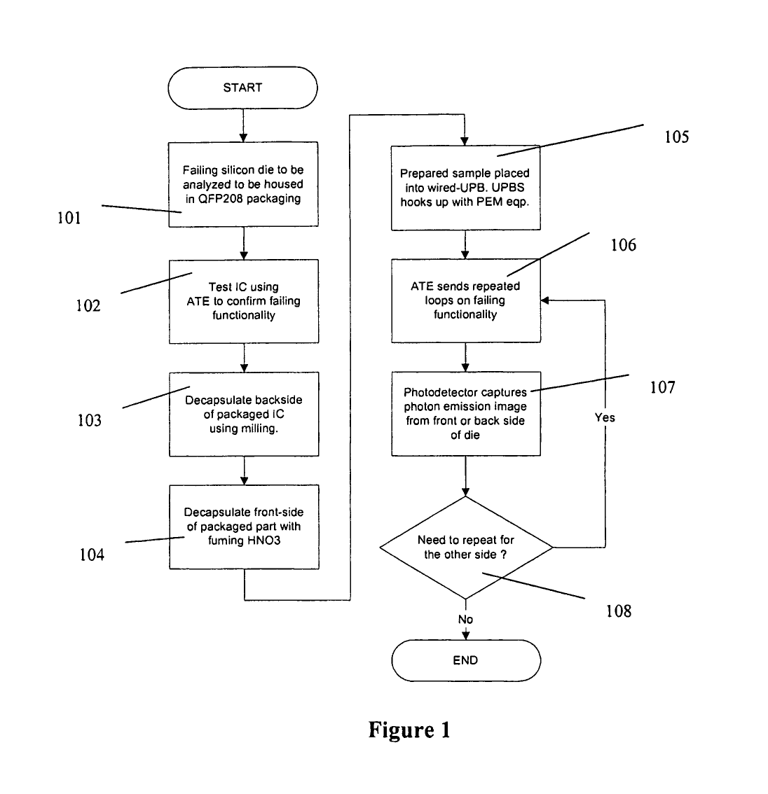

FIG. 2 is a block diagram of the system according to the invention illustrating the hardware components and the interconnection between the components; and

FIG. 3 is a block diagram of the system according to the invention illustrating the hardware components and the interconnection between the components, performing detection on the rear of an integrated circuit.

### BEST MODES FOR CARRYING OUT THE INVENTION

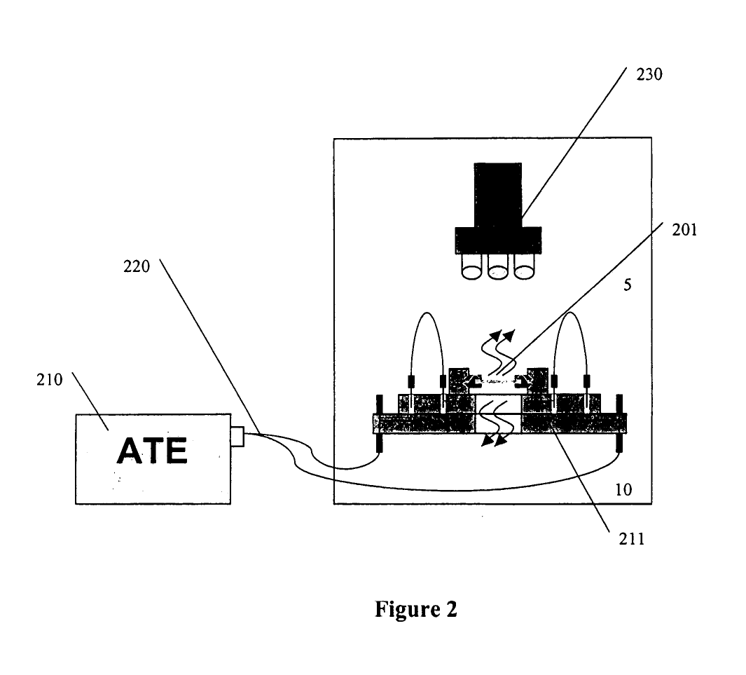

Referring to FIG. 2 an apparatus for testing emissions from an packaged integrated circuit is illustrated. The apparatus has an ATE 210 for generating input stimulus to the packaged integrated circuit 201. A universal PEM board 211 and an electrical connection 220 between the ATE 210 and the universal PEM 211 board are also provided.

Wires are used for connecting the ATE leads to pin leads of the packaged integrated circuit so that the packaged integrated circuit can be biased and stimulated correctly.

The system includes the use of jumper wires that provide many to one and one to many connections. This allows for flexibility in the circuits that can be tested.

The emission apparatus also includes a photodetector 230 to collect the emitted photons.

In order to use the present invention a packaged integrated circuit is decapsulated on both the front 105 and back 106 sides.

This is done as is known in the art using a diamond or carbide end mill tool on a milling machine on the back side 103. To prepare the front epoxy is used to hold the die prior to the back being decapsulated. Decapitation of the front side is typically done using HNO₃ 104

The package is then connected 105 to the ATE 210 and the ATE 210 is used to generate signals 106 in particular to failing functionality of the die. The photodetector 230 detects 107 any emissions from the die as a result of the signals from the ATE 210.

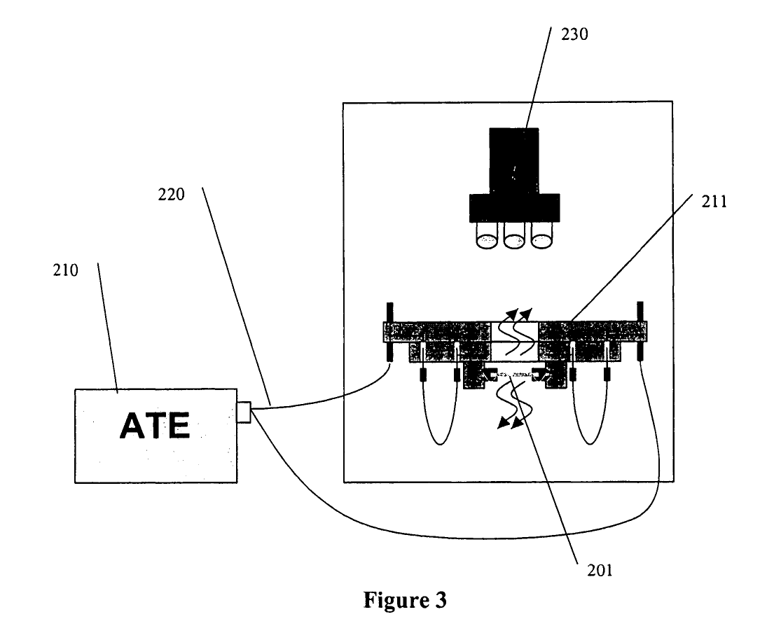

The present invention allows detection from the rear of the integrated circuit should that be necessary 108. This can be seen in FIG. 3 where the chip 201 has been flipped for exposure to the detector 230.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

1. An apparatus for testing emissions from a packaged integrated circuit having:
an ATE for generating input stimulus to said integrated circuit;
a universal PEM board;
an electrical connector between said ATE and said universal PEM board;
means for wiring the connections from ATE leads to pin leads of said packaged integrated circuit so that the packaged integrated circuit can be biased and stimulated correctly;
jumper wires providing the ability to allow many to one and one to many connections; and
a photodetector to collect the emitted photons.

2. An apparatus for testing emissions from a packaged integrated circuit as claimed in claim 1 wherein said means for wiring the connections from ATE leads to pin leads of said packaged integrated circuit is a UPB and wherein said UPB has an opening corresponding to the packaging to allow said photodetector access to the back of said packaged integrated circuit.

3. An apparatus for testing emissions from a packaged integrated circuit as claimed in claim 1 wherein said means for wiring the connections from ATE leads to pin leads of said packaged integrated circuit is a UPB and wherein said UPB has an opening corresponding to the packaging to allow said photodetector access to the front of said packaged integrated circuit.

4. An apparatus for testing emissions from a packaged integrated circuit as claimed in claim 1 wherein said apparatus allows both front and back detection of photo emissions.

5. An apparatus for testing emissions from a packaged integrated circuit as claimed in claim 2 wherein said apparatus allows both front and back detection of photo emissions.

6. An apparatus for testing emissions from a packaged integrated circuit as claimed in claim 3 wherein said apparatus allows both front and back detection of photo emissions.

7. An apparatus for testing emissions from a packaged integrated circuit as claimed in claim 1 wherein said jumper wires are pogo connectors.

8. An apparatus for testing emissions from a packaged integrated circuit as claimed in claim 2 wherein said jumper wires are pogo connectors.

9. An apparatus for testing emissions from a packaged integrated circuit as claimed in claim 3 wherein said jumper wires are pogo connectors.

10. An apparatus for testing emissions from a packaged integrated circuit as claimed in claim 4 wherein said jumper wires are pogo connectors.
